(19) United States
(12) Patent Application Publication
(10) Pub. No.: US 2013/0087463 A1
(43) Pub. Date: Apr. 11, 2013

(54) Method and System for Metal Deposition in Semiconductor Processing

(71) Applicants: Christian Schroiff, Dresden (DE); Michael Pietzner, Dresden (DE); Rico Bohla, Dresden (DE)

(72) Inventors: Christian Schroiff, Dresden (DE); Michael Pietzner, Dresden (DE); Rico Bohla, Dresden (DE)

(73) Assignee: GLOBALFOUNDRIES INC., Grand Cayman (KY)

(21) Appl. No.: 13/253,185

(22) Filed: Oct. 5, 2011

(51) Int. Cl. H01L 21/28; C25D 21/14; C25B 9/18; C25D 21/18; C25B 9/00

(52) U.S. Cl. 205/82; 205/101; 204/275.1; 204/269; 257/E21.158

(57) ABSTRACT

The present invention provides a system and a method for metal deposition in semiconductor processing, the system comprising a plating tool with one or more plating tanks, each containing one of a respective electrolyte solution, one or more replenishment sections each fluidly connected to a respective one of the one or more plating tanks, one or more draining sections each fluidly connected to a respective one of the one or more plating tanks, and a control system adapted to operate the one or more replenishing sections and/or the one or more draining sections so as to maintain a condition of the electrolyte solutions.

### BACKGROUND OF THE INVENTION

1. Field of the Invention

The present invention relates to an apparatus and method for metal deposition in semiconductor processing. Embodiments of the invention may relate to forming solder bumps and/or to forming underbump metallization structures which are used to provide contact areas for directly attaching an appropriately formed package or carrier substrate to a die carrying an integrated circuit.

2. Description of the Related Art

In manufacturing integrated circuits, it is usually necessary to package a chip and to provide leads and terminals for connecting the chip circuitry with the periphery. In some packaging techniques, chips, chip packages or other appropriate units may be connected by means of balls of solder or any other conductive material, formed from so-called solder bumps, that are formed on a corresponding layer, which will be referred to herein as a contact layer, of at least one of the units, for instance on a dielectric passivation layer of the micro-electronic chip. In order to connect the microelectronic chip with the corresponding carrier, the surfaces of the two respective units to be connected, i.e., a microelectronic chip comprising, for instance, a plurality of integrated circuits, and a corresponding package, have formed thereon adequate pad arrangements to electrically connect the two units after reflowing the bumps provided at least on one of the units, for instance, on the microelectronic chip. In other techniques, bumps may have to be formed that are to be connected to corresponding wires, or the bumps may be brought into contact with corresponding pad areas of another substrate acting as a heat sink. Consequently, it may be necessary to form a large number of bumps that may be distributed over the entire chip area, thereby providing, for example, the I/O capability required for modern microelectronic chips that usually include complex circuitry, such as microprocessors, storage circuits and the like, and/or include a plurality of integrated circuits forming a complete complex circuit system.

In order to provide hundreds or thousands of mechanically well-fastened bumps on corresponding pads, the attachment procedure of the bumps requires a careful design since the entire device may be rendered useless upon failure of only one of the bumps. For this reason, one or more carefully chosen layers are generally placed between the bumps and the underlying substrate or wafer including the pad arrangement. In addition to the important role these interfacial layers, herein also referred to as underbump metallization, may play in endowing a sufficient mechanical adhesion of the bump to the underlying pad and the surrounding passivation material, the underbump metallization has to meet further requirements with respect to diffusion characteristics and current conductivity. Regarding the former issue, the underbump metallization has to provide an adequate diffusion barrier to prevent the solder material or bump material, frequently a mixture of silver (Ag) and tin (Sn), from attacking the chip's underlying metallization layers and thereby destroying or negatively affecting their functionality. Moreover, migration of bump material, such as silver, to other sensitive device areas, such as dielectric layers, may also significantly deteriorate the device performance and has to be effectively suppressed by the underbump metallization. Regarding current conductivity, the underbump metallization, which serves as an interconnect between the bump and the underlying metallization layer of the chip, has to exhibit a thickness and a specific resistance that does not inappropriately increase the overall resistance of the metallization pad/bump system. In addition, the underbump metallization may serve as a current distribution layer during electroplating of the bump material.

Electroplating is presently the preferred deposition technique for solder material, since physical vapor deposition of solder bump material, which is also used in the art, requires a complex mask technology in order to avoid any misalignments due to thermal expansion of the mask while it is contacted by the hot metal vapors. Moreover, it is extremely difficult to remove the metal mask after completion of the deposition process without damaging the solder pads, particularly when large wafers are processed or the pitch between adjacent solder pads decreases. Although a mask is also used in the electroplating deposition method, this technique differs from the evaporation method in that the mask is created using photolithography to thereby avoid the above-identified problems caused by physical vapor deposition techniques.

However, when solder bumps are to be formed by electroplating, a continuous and highly uniform current distribution layer adhered to the substrate that is mainly insulative, except for the pads on which the bumps have to be formed, is required. Thus, the underbump metallization also has to meet strictly set constraints with respect to a uniform current distribution as any non-uniformities during the plating process may affect the final configuration of the bumps and, after reflowing the bumps, of the resulting solder balls in terms of, for instance, height non-uniformities, which may in turn translate into fluctuations of the finally obtained electric connections and the mechanical integrity thereof. Since the height of the bumps is determined by the local deposition rate during the electroplating process, which is per se a highly complex process, any process non-uniformity resulting from irregularities of the plating tool or any component thereof may also directly cause corresponding non-uniformities during the final assembly process. Moreover, since the formation of the bumps is one of the final steps that is performed on a substrate basis, any variations of the plating process or even loss of substrates due to tool failures immensely contributes to increased production costs and reduced yield.

FIG. 1 depicts in more detail a typical conventional process flow 100 for forming a contact layer and attaching the same to complex microelectronic chips directly with a carrier substrate.

In step 110, an underbump metallization layer 114 may be formed on a passivation layer 113 formed above a substrate 111, wherein the passivation layer 113 comprises an opening so as to expose a contact pad 112. Typically, the underbump metallization layer 114 is comprised of a plurality of individual layers, such as a titanium layer, a titanium tungsten layer and the like, for providing the required adhesion characteristics, followed by a barrier layer, such as a chromium, a chromium/copper layer, a nickel layer, or a nickel vanadium layer, providing the diffusion blocking effect, followed, for instance, by a final copper layer that may serve as a current distribution layer. Hereby, the thicknesses of the individual layers of the underbump metallization 114 are in general chosen to optimize the stress/thickness product, the diffusion properties and the mechanical integrity of the entire layer stack. The individual layers of the underbump metallization layer 114 are typically formed by sputter deposition or chemical vapor deposition, depending on the type of material used.

Next, in step 120, a lithography process is performed so as to form a resist mask 121 above the underbump metallization layer 114, wherein the resist mask 121 has an opening formed therein so as to define the dimensions and the shape of a solder bump to be formed therein. In step 130, a solder bump 131 is formed by means of the resist mask 121, for instance, by electroplating, wherein at least the uppermost layer of the underbump metallization layer 114 acts as an efficient current distribution layer, as already previously described. Thereafter, in step 140, the resist mask 121 is removed by well-known wet chemical strip methods or dry etch techniques. Next, in step 150, the underbump metallization layer 114 is patterned by means of wet chemical or electrochemical etch techniques, which require a highly complex etch chemistry owing to the variety of materials, which may per se individually require complex etch procedures. Moreover, due to the complexity of process steps and etch chemistries, several cleaning steps are usually required for removing any byproduct created during the individual etch procedures.

Next, in step 160, a final cleaning step is performed so as to remove contaminants and byproducts from the preceding step 150 from the solder bump 131, thereby preparing it for a following reflow process in step 170 so as to form a rounded solder ball 171. During reflow, the solder material, especially any tin contained therein, may form an intermetallic phase with copper contained in the uppermost sub-layer of the underbump metallization layer 114, thereby creating a reliable metallization interface.

In step 180, the solder balls 171 may be tested in view of electrical and/or mechanical functionality. Finally, in step 190, the device represented by the substrate 111 may be assembled, that is, may be attached to a corresponding substrate having formed thereon respective contact pads, which may be brought into contact with the solder balls 171 upon reflowing the solder balls 171.

A process of plating deposition of solder bumps is disclosed in US Patent Publication 2006/0172444 A1.

Electroplating is primarily used for depositing a layer of material on a substrate by means of an electric current flow when applying a voltage. The amount of material deposited per time, the so-called deposition rate, is directly related to the amount of electric current. A conventional electroplating cell comprises a tank containing an aqueous solution and electrodes, i.e., a cathode and an anode. Usually, the cathode is formed by the substrate on which material is to be deposited. The aqueous solution contained in the tank generally consists of an electrolyte solution which comprises metal ions of metal material to be deposited. The electrolyte solution is prepared by dissolving a metal salt of the metal material to be deposited. When dissolving the metal salt, it disassociates into positively charged metal ions, so-called cations, and negatively charged non-metallic ions, so-called anions. Accordingly, the electrolyte solution permits the flow of electricity when a voltage is applied to the electrodes as it is explained below.

Electroplating deposition can only be performed when an according depositing current flows. This is the case when an applied voltage is greater than or equal to a certain voltage drop over the electrodes. This voltage drop depends on many factors, such as the kind of material used as electrode material, the concentration of metal ions in an electrolyte solution, the standard reduction/oxidation potential of the metal to be deposited, a temperature of the electrolyte solution, a pH value and the like. Herein, the standard reduction/oxidation potential represents a tendency of a chemical species to acquire/lose electrons, thereby being reduced/oxidized with respect to a reference chemical species, often hydrogen, to which a standard reduction/oxidation potential equal to zero is assigned. Once a sufficiently high voltage is applied, an electric field builds up between the electrodes causing migration of ions and establishing a current from the anode to the cathode. This current oxidizes the anode material whereby the anode dissolves. Metal ions in the electrolyte solution migrate to the cathode due to the electric field and are subsequently reduced at the interface between the electrolyte solution and the cathode. Reduction of metal ions means that metal ions acquire electrons and the metal is deposited on the cathode.

Apparently, the amount of current flowing between the electrodes is related to the amount of material which is deposited on the cathode per time and thus to the deposition rate. Clearly, the anode must be occasionally renewed in order to maintain a sufficient amount of metal ions in the electrolyte solution and thus to sustain reduction and deposition of metal on the cathode. Therefore, the electroplating cell can only be operated with interruptions during which the anode is replaced and the electroplating cell is not operated. According to another technique, usage of a non-consumable anode, such as a lead anode or the like, may avoid dissolution of the anode but draws out metal ions from the electrolyte solution, thus diminishing the concentration of metal ions.

With reference to FIG. 2, a conventional plating equipment will be briefly described. FIG. 2 schematically shows a plating apparatus 200 as it is used, for example, for forming solder bumps.

As it is shown in FIG. 2, a plating tank 220 is provided which contains an electrolyte solution comprising tin (Sn) ions and silver (Ag) ions. The electrolyte solution is prepared by dissociating respective metal salts which dissolve in the electrolyte solution as explained above. The SnAg plating process depends critically on the concentration of metal ions in the plating bath. Especially when a non-consumable anode is used, the concentration of metal ions is depleted during the plating process as material is deposited on the pads, e.g., for forming bumps, and metal ions are drawn out from the electrolyte solution. To maintain a stable plating performance, the depleted bath components, such as tin and silver, must be replenished regularly from a replenishment system, comprising a replenishment pump 240 and a reservoir 260, each for any single component of the electrolyte solution which is depleted during electroplating. The replenishment pump 240 conveys components to be replenished from the reservoir 260 to the plating tank 220 via a duct 244.

The plating tank 220 further comprises a sensor 222 to detect a concentration of metal ions in the electrolyte solution and to output signals to a control system 280 via a control line 284. In general, the control system 280 is configured to receive the signals provided by the sensor 222 and to transmit control signals to the replenishment pump 240 via a control line 288, controlling the operation of the replenishment pump 240. The plating apparatus 200 shown in FIG. 2 may be semi-automated or fully automated, time-controlled and/or analysis based.

If the single components of the electrolyte solution are replenished in the bath by means of a component replenishment system, the total volume of the electrolyte solution in the plating tank increases, thus changing an immersion depth of the electrodes, i.e., of the cathode, in the electrolyte solution. A change of the immersion depth may lead to an inhomogeneous deposition. Material may be deposited on portions of the cathode on which material is not to be deposited, such as cathode connection terminals or the like, deteriorating electrical contacts, wasting material and thus increasing overall production costs.

Furthermore, the concentration of metal ions in the electrolyte solution is not kept constant: the concentration of the metal ions decreases during the plating process and increases during the replenishing process. The course of a concentration-time curve when plotting concentration over time rather resembles a saw tooth than that of a horizontal straight line. The reason is that, due to a change in the total volume of the electrolyte solution, the concentration of metal ions in the electrolyte solution is unavoidably changed as well. As the concentration of the metal ions is in turn related to the amount of current flowing from the anode to the cathode, the deposition rate is also affected. Therefore, a reliably controlled deposition is not given and a desired level of concentration and consequently a desired deposition rate cannot be reliably sustained. When forming solder bumps by electroplating, varying deposition rates during the plating process unavoidably affect the configuration of the bumps by introducing non-uniformities. As it is explained above, after reflowing, these non-uniformities result in solder balls of varying shapes, sizes and/or heights, thus leading to defective devices and/or devices of deteriorated performance.

As a result, in the typical conventional process explained above, complex adjustment of the concentration of metal ions in the electrolyte solution and/or of the electric current flow depending on the concentration of metal ions present and on the volume of the electrolyte solution must be involved in order to reliably provide a controlled deposition process. Furthermore, when an amount of replenished solution exceeds the maximum level of the plating tank, electroplating has to be interrupted and the content of the plating tank has to be renewed again. During these interruptions, electroplating cannot be performed and production time is prolonged.

In view of the above-described situation, a need exists for an enhanced apparatus that may avoid or at least reduce the effects of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a system and method for metal deposition in semiconductor processing providing an improved and reliable deposition of metal on a semiconductor device. For this purpose, a condition of an electrolyte solution is maintained, thereby performing homogeneous and uniform deposition and thus significantly enhancing process control and production yield and reducing waste of material.

According to one illustrative embodiment of the present invention, a system for metal deposition in semiconductor processing comprises a plating tool, one or more replenishment sections, one or more draining sections and a control system. The plating tool has one or more plating tanks, wherein each plating tank contains one of a respective electrolyte solution. The one or more replenishment sections are each fluidly connected to the one or more plating tanks. The one or more draining sections are each fluidly connected to a respective one of the one or more plating tanks. Furthermore, the control system is configured to operate at least one of the one or more replenishing sections and the one or more draining sections so as to maintain a condition of the electrolyte solutions.

In accordance with another illustrative embodiment of the present invention, a method for metal deposition in semiconductor processing comprises replenishing one or more plating tanks of a plating tool by a plurality of replenishment sections, each of the one or more plating tanks having an electrolyte solution, and controlling a draining of the electrolyte solution from said one or more plating tanks by one or more draining sections such that the amount of solution the one or more plating tanks are replenished with is drained from the one or more plating tanks.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically shows a process flow for forming a contact layer in accordance with a typical conventional technique;

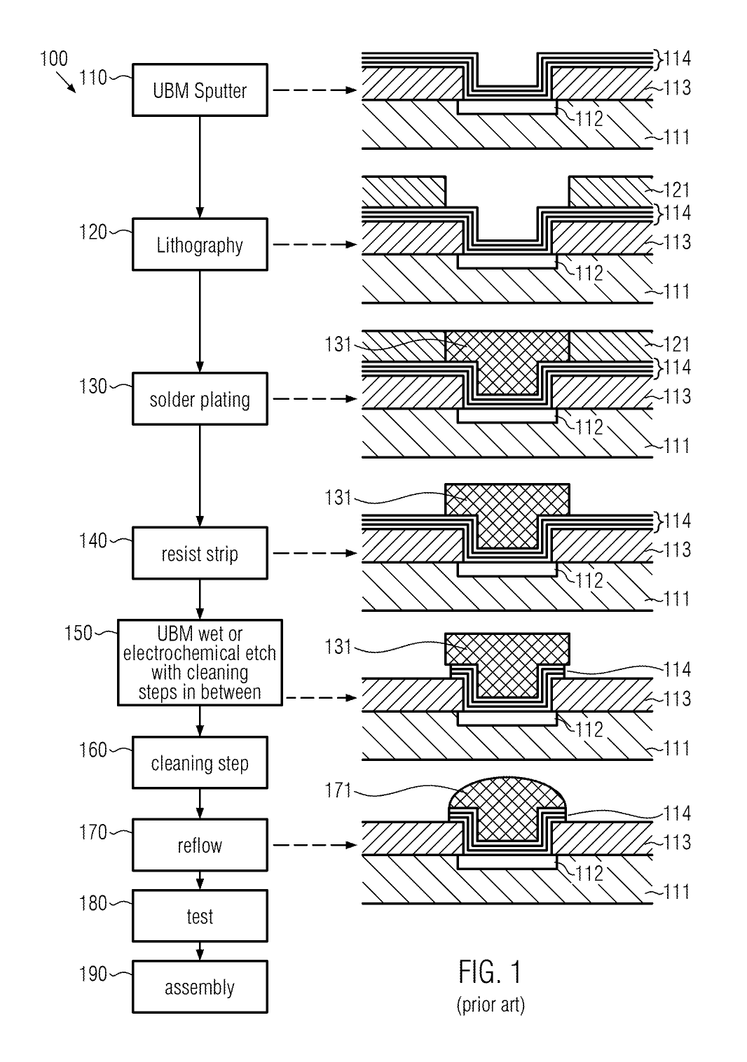

FIG. 2 shows a schematic view of a conventional plating apparatus;

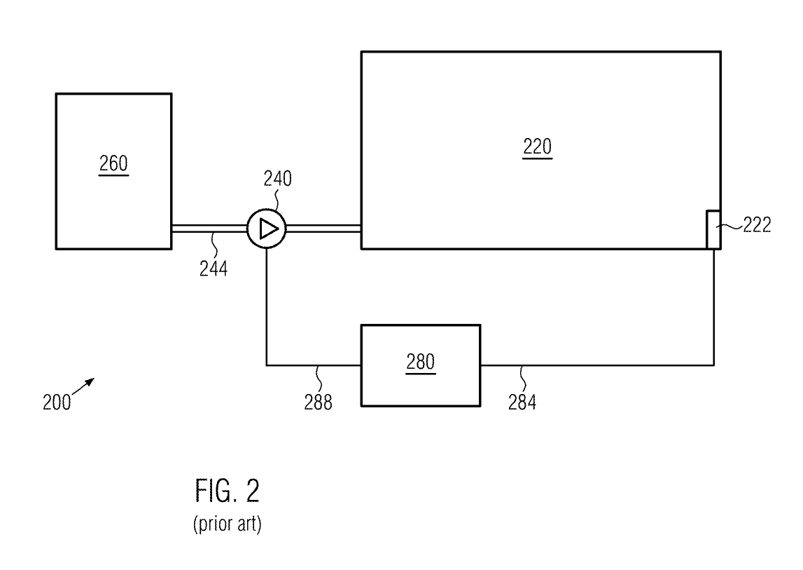

FIG. 3 schematically shows a plating system for forming bumps on a substrate according to illustrative embodiments of the present invention; and

FIG. 4 schematically shows a plating system for forming bumps on a substrate according to other illustrative embodiments of the present invention.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention is generally based on the concept of controlling replenishment and draining of a plating tank in dependence on conditions of an electrolyte solution in the plating tank. The controlling allows for maintaining at least one of the conditions of the electrolyte solution. By maintaining at least one condition of the electrolyte solution, a homogeneous deposition of, for example, solder material on pads of semiconductor substrates for processing microchips is achieved to a high degree of accuracy such that unwanted deviations, for example, in a height of deposited solder material, deteriorating electrical or mechanical connections are avoided.

A condition of an electrolyte solution may comprise at least one of a total volume of the electrolyte solution, a filling elevation of the electrolyte solution in a plating tank, a parameter of the electrolyte solution relating to an immersion depth of at least one electrode in the electrolyte solution, a concentration of at least one component dissolved in the electrolyte solution, a temperature of the electrolyte solution, an amount of substance of at least one species contained in the electrolyte solution, a current flowing through at least one electrode, a resistivity of the electrolyte solution, a conductivity of the electrolyte solution, a pH value and the like.

According to an illustrative embodiment of the present invention, an appropriate monitoring of at least one condition of an electrolyte solution and a controlling of a replenishment of according components which are deposited during an electro-deposition and draining of electrolyte solution in dependence on at least one monitored condition of the electrolyte solution may enable the replenishment and draining, wherein an excess amount of replenished electrolyte solution is drained out of the plating tank concurrently or consecutively to the replenishment of the excess amount of replenished electrolyte solution or vice versa. Accordingly, the total volume may be sustained at a substantially constant level when replenishing a certain amount of excess volume to the electrolyte solution when draining the amount of excess volume from the electrolyte solution. The amount of components replenished by the excess volume may be determined so as to adjust and/or to sustain a desired level of concentration of at least one component in the electrolyte solution and/or to maintain a temperature of the electrolyte solution at a constant level and/or to adjust and/or to sustain a current flow through at least one electrode at a desired level and/or to adjust and/or to sustain a pH value of the electrolyte solution.

According to a further illustrative embodiment of the present invention, an appropriate monitoring of at least one condition of an electrolyte solution in a plating tank and a controlling of replenishing at least of one or more components of the electrolyte solution may depend on at least one condition of the electrolyte solution enabling the replenishing and draining of an amount of electrolyte solution from the plating tank. Herein an excess amount of replenished electrolyte solution is drained out of the plating tank concurrently or consecutively to the replenishment of an excess amount of replenished electrolyte solution or vice versa. In accordance with this illustrative example, the total volume and/or the temperature of the electrolyte solution and/or a concentration of at least one component of the electrolyte solution and/or a current flow through at least one electrode and/or a temperature of the electrolyte solution and/or a pH value of the electrolyte solution is sustained at a substantially constant level by replenishing a certain amount of excess volume to the electrolyte solution. The same amount of excess volume may be drained from the electrolyte solution and the total volume of electrolyte solution may be sustained at a constant level. The amount of components replenished by the excess volume may be further determined so as to adjust and/or to sustain a desired level of concentration of at least one component in the electrolyte solution and/or to maintain a temperature of the electrolyte solution at a constant level and/or to adjust and/or to sustain a current flow through at least one electrode at a desired level and/or to adjust and/or to sustain a pH value of the electrolyte solution.

When preparing a solution of a salt, in dependence on exterior conditions, such as pressure, concentration of dissociated ions, temperature and the like, either dissociation or recombination of dissociated ions is preferred. When changing exterior conditions, then a change in the preferred direction may be obtained and, for example, ions of a dissolved salt may preferably recombine such that the dissolved salt may precipitate. Accordingly, the concentration of ions decreases when a salt precipitates from a solution. Therefore, it may be advantageous to control a temperature of an electrolyte solution and/or to control a concentration of ions in a solution when adjustment of an amount of ions dissolved in a solution is desired.

Components of the electrolyte solution may further comprise at least one of inorganic additives, organic additives, metal ions of one or more metal species and leveling agents. Herein, the organic additives and/or the inorganic additives may be added to affect at least one of shape, profile, roughness and uniformity of the deposited material.

With reference to the accompanying drawings, further illustrative embodiments of the present invention will now be described in more detail.

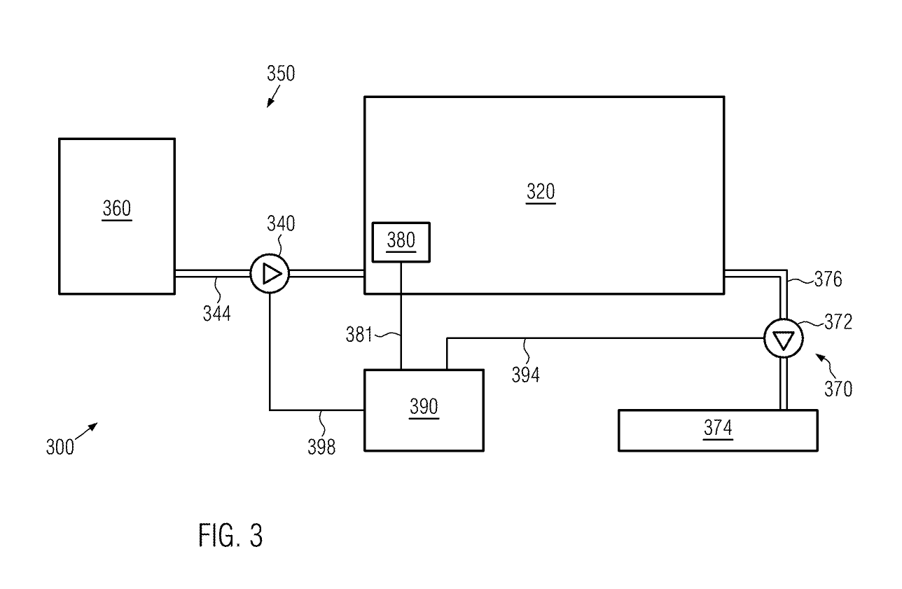

FIG. 3 schematically shows a system 300 for metal deposition in semiconductor processing providing a plating tank 320. Herein, substrates, such as semiconductor dies, chips or the like, may receive metal bumps by electroplating. The plating tank 320 contains an electrolyte solution. The electrolyte solution may be readily provided or may be prepared by dissolving respective metal salts, dissociating into positively charged metal ions and negatively charged anions. The metal ions correspond to metals which are to be electroplated on substrates. The metal salts may comprise at least one of Sn and Ag when SnAg-plating is performed.

In FIG. 3, there is shown a replenishment section 350 comprising a replenishing pump 340 and a reservoir 360 providing a solution comprising metal ions. The replenishment pump 360 is connected to the plating tank 320 and to the reservoir 360 via a duct 344 and it is configured to convey solution from the reservoir 360 to the plating tank 320. The solution contained in the reservoir 360 may comprise metal ions of metal species which are to be replenished to the electrolyte solution in the plating tank 320. According to special illustrative embodiments, the metal species may be at least one of tin and silver. However, it is appreciated that the metal species are not limited to tin and silver, but may be any kind of metal to be deposited on a substrate by electroplating.

The system 300 shown in FIG. 3 is also not limited to comprise a single replenishment section 350 but may instead comprise two, three or any number of replenishment sections which are accordingly connected to the plating tank 320. The number of replenishment sections may depend on the number of different species of metal to be deposited. The one or more replenishment sections may comprise one replenishment pump or one replenishment pump in each replenishment section.

The system 300 as shown schematically in FIG. 3 further comprises a draining section 370. The draining section 370 comprises a draining pump 372 and a reservoir 374 fluidly connected to the plating tank 320 via a duct 376. The draining pump 372 may convey electrolyte solution from the plating tank 320 to the reservoir 374 via the duct 376.

The system 300 is not limited to comprise one draining section 370, but may instead comprise two, three or any number of draining sections which may be accordingly connected to the plating tank 320. The one or more draining sections may comprise one draining pump or one draining pump in each draining section.

FIG. 3 further shows a control system 390 coupled to the draining section 370, i.e., to the draining pump 372, via a control line 394, and to the replenishment section 350, i.e., to the replenishment pump 340, via a control line 398. It is appreciated that the control lines 394 and 398 may not necessarily be physical lines but may represent general couplings which may also be established by transmittance of any kind of appropriate detectable signal, such as electromagnetic radiation or the like. It is further appreciated that, in embodiments having at least one of several draining sections, respectively draining pumps, and several replenishment sections, respectively replenishment pumps, each section, respectively each pump, may be individually or section wise coupled to the control systems 390 or to a plurality of control systems which are each coupled to respective draining pumps and/or replenishment pumps.

The system 300 may further comprise one or more sensors 380 which may be coupled to the control system 390 via coupling lines 381. It is appreciated that the coupling lines 381 may not necessarily be physical lines but may represent general couplings which may also be established by transmittance of any kind of appropriate detectable signal such as electromagnetic radiation or the like. The one or more sensors 380 may be configured to detect at least one of a concentration of at least a component of electrolyte solution, any appropriate parameter to determine a volume of the electrolyte solution, a filling elevation of the electrolyte solution within the plating tank 320, a current flow through at least one electrode, a temperature of the electrolyte solution, a conductivity of the electrolyte solution in the plating tank 320, a resistance of the electrolyte solution in the plating tank 320, a pH value and the like.

An operation of the system 300 shown in FIG. 3 according to one illustrative embodiment of the present invention is briefly described as follows. As soon as one or more conditions of the electrolyte solution in the plating tank 320 change such that predetermined boundaries are reached or passed, one or more sensors 380 may provide one or more electrical signals to the control system 390. The control system 390 may activate the replenishment pump 340 of the replenishment section 350 and the draining pump 372 of the draining section 370. The activation of the replenishment pump 340 and the activation of the draining pump 372 may be effected simultaneously, concurrently or consecutively. The replenishment pump 340 may replenish a solution comprising metal ions corresponding to metals to be deposited to the plating tank 320. The draining pump 372 may be controlled by the control system 390 so as to pump a volume of the electrolyte solution from the plating tank 320 to the reservoir 374 which is equal to the volume provided by the replenishment pump 340 during the replenishment.

According to illustrative embodiments of the invention effecting a simultaneous pumping of the replenishment pump 340 and the draining pump 372, the control system 390 may provide simultaneous signals to the replenishment pump 340 and to the draining pump 372 starting and stopping the pumps simultaneously. It is appreciated that, in case of the system 300 comprising at least one of several replenishment pumps and several draining pumps, the pumps may be controlled by simultaneous signals individually fed to each pump, fed to respective pairs of pumps or fed to respective groups of pumps via corresponding control lines as explained above. It is appreciated that the simultaneous pumping may be performed continuously or according to predetermined schedules or in dependence on one or more conditions of the electrolyte solution. It is further appreciated that the simultaneous pumping may be performed at equal flow rates in the replenishment section 350 and in the drain section 370. The controlling may be effected in dependence on a signal output to the control system 390 by one or more sensors 380. The signal output by the one or more sensors may comprise one or more signals relating to at least one of a concentration of at least a component of the electrolyte solution in the plating tank 320, a volume of the electrolyte solution in the plating tank 320, a filling elevation of the electrolyte solution within the plating tank 320, a conductivity of the electrolyte solution in the plating tank 320, a resistance of the electrolyte solution in the plating tank 320, an amount of current flow through at least one electrode, a temperature within the plating tank 320, a pH value and the like.

According to other illustrative embodiments of the invention effecting a concurrent pumping of the replenishment pump 340 and the draining pump 372, the control system 390 may provide a signal to the replenishment section 350 controlling the replenishment pump 340 to effect a start or a stop operation of the replenishment pump 340 and may subsequently provide a signal to the draining section 370 controlling the draining pump 372 to effect a start operation of the draining pump 372 when a start operation of the replenishment pump 340 was effected or to effect a stop operation of the draining pump 372 when a stop operation of the replenishment pump 340 was effected. It is appreciated that the control system 390 may alternatively provide a signal to the draining section 370 controlling the draining pump 372 to effect a start or a stop operation of the draining pump 372 and may subsequently provide a signal to the replenishment section 350 controlling the replenishment pump 340 to effect a start operation of the replenishment pump 340 when a start operation of the draining pump 372 was effected or to effect a stop operation of the replenishment pump 340 when a stop operation of the draining pump 372 was effected. The controlling may be effected according to predetermined schedules or in dependence on at least one condition of the electrolyte solution or in dependence on a signal output to the control system 390 by one or more sensors 380. The signal output by the one or more sensors 380 may comprise one or more signals relating to at least one of a concentration of at least one component of the electrolyte solution in the plating tank 320, a volume of the electrolyte solution in the plating tank 320, a filling elevation of the electrolyte solution within the plating tank 320, a conductivity of the electrolyte solution in the plating tank 320, a resistance of the electrolyte solution in the plating tank 320, an amount of current flow through at least one electrode, a temperature within the plating tank 320, a pH value and the like. A time delay between a provision of a control signal effecting a start or stop operation to a first pump prior to a provision of a control signal effecting a start or stop operation to a second pump may be on the order of milliseconds or on the order of seconds or on the order of several ten seconds. It is appreciated that in case of the system 300 comprising at least one of several replenishment pumps and several draining pumps, the pumps may be controlled by concurrent signals individually fed to each pump, fed to respective pairs of pumps or fed to respective groups of pumps via according control lines as explained above.

According to further illustrative embodiments of the present invention effecting a consecutive pumping of the replenishment pump 340 and the draining pump 372, the control system 390 may provide a signal to the replenishment section 350 controlling the replenishment pump 340 to effect a start and a stop operation of the replenishment pump 340, thereby replenishing a certain volume of solution from reservoir 360 to plating tank 320. Subsequently, the control system 390 may provide a signal to the draining section 370 controlling the draining pump 372 to effect a start and a stop operation of the draining pump 372 to subsequently remove the same volume of electrolyte solution from the plating tank 320 so as to keep the total volume of electrolyte solution after the draining equal to the total volume of electrolyte solution in the plating tank before the replenishment was performed. It is appreciated that the control system 390 may alternatively provide a signal to the draining section 370 controlling the draining pump 372 to effect a start and a stop operation of the draining pump 372 removing a certain volume of solution from the plating tank 320 which is fed to reservoir 374. Subsequently, the control system 390 may provide a signal to the replenishment section 350 controlling the replenishment pump 340 to effect a start and a stop operation of the replenishment pump 340 to subsequently feed the same volume of solution from the reservoir 360 to the plating tank 320 so as to keep the total volume of electrolyte solution after replenishment equal to the total volume of electrolyte solution in the plating tank before replenishment. The controlling may be effected in dependence on at least one condition of the electrolyte solution or a signal output to the control system 390 by one or more sensors 380 or on predetermined schedules. The signal output by the one or more sensors 380 may comprise one or more signals relating to at least one of a concentration of at least one component of the electrolyte solution in the plating tank 320, a volume of the electrolyte solution in the plating tank 320, a filling elevation of the electrolyte solution within the plating tank 320, a conductivity of the electrolyte solution in the plating tank 320, a resistance of the electrolyte solution in the plating tank 320, an amount of current flow through at least one electrode, a temperature within the plating tank 320, a pH value and the like. A time delay between a provision of a control signal effecting a start and stop operation to a first pump prior to a provision of a control signal effecting a start and stop operation to a second pump may be on the order of milliseconds or on the order of seconds or on the order of several ten seconds or on the order of minutes. It is appreciated that in case of the system 300 comprising at least one of several replenishment pumps and several draining pumps, the pumps are controlled by consecutive signals individually fed to each pump, fed to respective pairs of pumps or fed to respective groups of pumps via according control lines as explained above.

According to further illustrative embodiments of the present invention, a controlling of the replenishment pump 340 or of the draining pump 372 may be effected by the control system 390 as soon as at least one condition of the electrolyte solution reaches or exceeds a maximum or minimum allowed boundary value for a concentration of at least one component of the electrolyte solution, a current flow through at least one electrode, resistivity of the electrolyte solution, conductivity of the electrolyte solution, a temperature within the plating tank 320, a pH value and the like. The one or more sensors 380 may provide one or more according signals to the control system 390. The control system 390 may provide input signals to the replenishment section 350 and to the drain section 370 effecting start and stop operations of the respective pumps as it is explained above.

It is appreciated that systems as described with reference to FIG. 3 may comprise more than one reservoir 360. The number of reservoirs may depend on the number of components of the electrolyte solution. Each component may be provided by a respective reservoir. A reservoir may further comprise one or more canisters providing solution for replenishment.

In illustrative embodiments according to which a consecutive operation of the replenishment pump 340 and the drain pump 372 is performed as explained above, one or more replenishment pumps fluidly connected to one or more reservoirs may be used. In illustrative embodiments according to which a simultaneous operation of the replenishment pump 340 and the draining pump 372 is performed as explained above, one or more replenishment pumps fluidly connected to one or more reservoirs and one or more draining pumps may be provided such that the amount of solution the plating tank 320 is replenished with is removed by the one or more draining pumps.

It is appreciated that the reservoir 374 of the draining section 370 may comprise one or more canisters which are fluidly coupled such that once a canister is full, another canister may be filled. Therefore, the production does not have to be interrupted when a canister is filled with drained electrolyte solution. It is appreciated that one draining pump may be fluidly connected to one or more canisters or that each draining pump is fluidly connected to one canister.

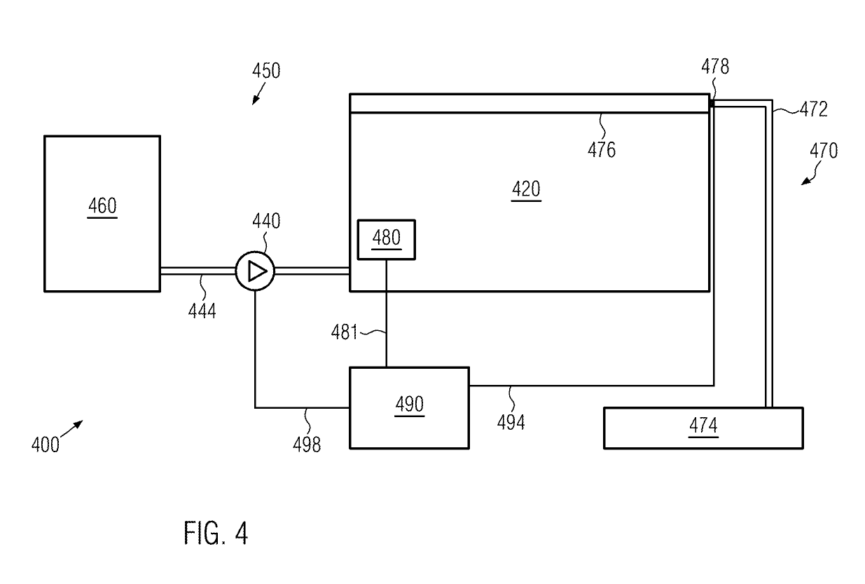

Another illustrative embodiment of the present invention will be explained with regard to FIG. 4. FIG. 4 shows schematically a system 400 for metal deposition in semiconductor processing. The system 400 comprises a plating tank 420, a replenishment section 450, a draining section 470 and a control system 490. The replenishment section 450 provides a replenishment pump 440 and a reservoir 460 which is fluidly connected to the plating tank 420 via a duct 444. The control system 490 is coupled to the replenishment pump via a control line 498. It is appreciated that the control line 498 may not necessarily be a physical line but may represent general couplings which may also be established by trans-mittance of any kind of appropriate detectable signals, such as electromagnetic radiation or the like. The replenishment section 450 may show one or more technical features and characteristics as it is explained above with reference to the replenishment section 350 shown in FIG. 3.

Reference numeral 470 in FIG. 4 denotes a draining section 470 which provides an overflow or spillover 472 fluidly connected to a reservoir 474. The reservoir 474 may be formed in accordance with the reservoir 374 as it is explained above with reference to FIG. 3. The overflow or spillover 472 may be formed so as to drain any amount of electrolyte solution from the plating tank 420 once the volume of electrolyte solution exceeds a predetermined volume, which is indicated in FIG. 4 by reference numeral 476. The overflow or spillover 472 may comprise one or more tubes being attached to the plating tank 420. Note that the draining may be effected due to gravitational forces.

The draining system 470 further comprises a gate 478 which is coupled to the control system 490 via a control line 494. The control line 494 may be formed in accordance with the control line 394 which is described with reference to FIG. 3. The control system 490 may control the gate 478 such that the gate may be opened or closed upon receipt of respective signals output by the control system 490.

It is appreciated that the overflow or spillover 472 is not limited by the above given example. It may be connected to the plating tank 420 at any height and, for example, may be formed as an outlet located underneath a filling elevation of electrolyte solution in the plating tank 420.

The system 400 may further comprise one or more sensors 480 coupled to the control system with a line 481. The one or more sensors 480 may be formed as it is explained above with reference to FIG. 3.

An operation of the system 400 according to one illustrative embodiment will be described. Prior to plating, an electrolyte solution is filled into the plating tank 420 such that the electrolyte solution reaches at least the overflow or spillover 472 and any additional amount of electrolyte solution will cause overflow. Accordingly, a minimum level of the electrolyte solution is represented by 476 in FIG. 4.

The control system 490 may transmit a control signal to the replenishment pump 440 via the control line 498 in order to effect a start or stop operation of the replenishment pump 440 so as to replenish metal ions to the plating tank 420 as it is described with reference to FIG. 3 above. The control system 490 may be configured to simultaneously, concurrently or consecutively operate the replenishment pump 440 and the gate 478 by transmitting control signals to the replenishment pump 440 and to the gate 478. An operation of the draining section 470 and of the gate 478 may be performed in accordance with an operation of the draining section 370 as it is described above.

When replenishing solution to the electrolyte solution in plating tank 420, electrolyte solution flows into reservoir 474 via overflow or spillover 472 until the control system 490 transmits a control signal to the gate 478 to shut the gate 478. It is appreciated that the duct 444 connecting the plating tank 420 and the reservoir 460 may be attached to the plating tank 420 at a lower portion of the plating tank 420 or at any other appropriate position on the plating tank 420 in order to provide sufficient mixing of the solution with the electrolyte solution in the plating tank 420 and sufficient draining of electrolyte solution.

The control system 490 may control the replenishment pump 440 and the gate 478 so as to operate continuously or in predetermined time intervals. The control system 490 may be additionally or alternatively coupled to the one or more sensors 480 outputting signals to the control system 490 via line 481. The controlling of the replenishment pump 440 and the gate 478 by the control system 490 may be effected in dependence on the signals output to the control system 490. Possible sensors and sensor signals are described above with reference to FIG. 3.

It is appreciated that the illustrative embodiments described above may further allow for a reconditioning of electrolyte solution removed from a plating tank by a draining section and fed to according reservoirs. An appropriate reconditioning system may be connected to the draining section for reprocessing the electrolyte solution removed by the draining section and feeding the reprocessed solution directly back to the plating tank or feeding the reprocessed solution to a reservoir of a replenishment section. For example, the electrolyte solution collected in the reservoir of a draining system may be reused after reprocessing to refill the plating tank or a reservoir of a replenishment section instead of changing the complete bath in the plating tank. Therefore, time intervals between a total exchange of electrolyte solution in plating tanks may be considerably prolonged or even avoided, thus allowing for a continuous operation of a plating system.

The person skilled in the art will appreciate that replenishment sections as they are described with respect to illustrative embodiments regarding electroplating may not be limited to electroplating systems. Replenishment sections may be used in systems for electroless deposition as well. In electroless deposition, solutions are used which comprise reducing agents and metal ions of metal materials to be deposited. Replenishment sections as used in electroless deposition may further provide for replenishment of an activating agent to activate a reducing agent. It is appreciated that replenishment sections as described with regard to illustrative embodiments of the present invention may be accordingly used in electroless deposition, as well, taking the above said into account.

The person skilled in the art will appreciate that draining sections as they are described with respect to illustrative embodiments regarding electroplating may not be limited to electroplating systems. Draining sections may be used in systems for electroless deposition as well. It is appreciated that draining sections described with regard to illustrative embodiments of the present invention may be accordingly used in electroless deposition as well, taking the above said into account.

The person skilled in the art will appreciate that the illustrative embodiment as described with regard to FIG. 4 is not limited to comprise a replenishment section having a replenishment pump. It is also possible to modify the replenishment section in accordance with the draining section 470 shown in FIG. 4 such that reservoirs of the replenishment section are located above the plating. By means of an according gate, reservoirs of the replenishment section may be fluidly connected to a plating tank, replenishing the plating tank with a solution contained in the reservoir when the gate is opened.

The person skilled in the art will appreciate that technical features and characteristics that are described with reference to an illustrative embodiment or to a group of illustrative embodiments may not be limited to the illustrative embodiment or to the group of illustrative embodiments they are described with, but may be present in other illustrative embodiments as well.

As a result, the present invention provides a system and a method that provides significantly increased process reliability by simultaneously replenishing electrolyte solution to the plating tank while draining the excess of electrolyte solution during the refill of single components of the electrolyte solution in the bath of an electroplating tank. In particular embodiments, the excess solution may be drained into canisters from the plating tank simultaneously while the plating tank is replenished by the single components of the electrolyte solution, thus substantially maintaining the level of electrolyte solution in the plating tank. In particular embodiments, the excess solution may be removed from the plating tank simultaneously, concurrently or consecutively with the replenishment of the single components of electrolyte solution, thus maintaining the level of electrolyte solution in the plating tank to the operation level, as well as maintaining at least one condition of the electrolyte solution. In particular embodiments, the amount of electrolyte solution drained into the canisters may be at least the same amount of electrolyte solution the plating tank is replenished with during operation of the plating apparatus, in order to be reused to fill the plating tank with new electrolyte solution when a complete change of the bath is needed. Consequently, a process control during processing is established that may be operated to refill the tank during processing, thereby significantly reducing interruptions of the plating process due to unscheduled maintenance time.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A system for metal deposition in semiconductor processing, the system comprising:
a plating tool with one or more plating tanks, each for containing one of a respective electrolyte solution;
one or more replenishment sections, each being fluidly connected to a respective one of said one or more plating tanks;
one or more draining sections, each being fluidly connected to a respective one of said one or more plating tanks; and
a control system adapted to operate at least one of the one or more replenishing sections and the one or more draining sections so as to maintain at least one condition of the respective electrolyte solutions.

2. The system of claim 1, wherein the at least one condition of the respective electrolyte solutions comprises at least one of a total volume of the electrolyte solution, a filling elevation of the electrolyte solution in a plating tank, a parameter of the electrolyte solution relating to an immersion depth of at least one electrode in the electrolyte solution, a concentration of at least one component dissolved in the electrolyte solution, a temperature of the electrolyte solution, an amount of substance of at least one species contained in the electrolyte solution, a current flowing through at least one electrode, a resistivity of the electrolyte solution, a conductivity of the electrolyte solution, a pH value and the like.

3. The system of claim 1, wherein at least one of each draining section and each replenishment section comprises a pump.

4. The system of claim 3, wherein at least one of each draining section and each replenishment section further comprises a canister fluidly connected to the pump.

5. The system of claim 1, wherein at least one of each replenishment section and each draining section comprises a gate and a reservoir, wherein each gate is configured to fluidly connect each reservoir to said one or more plating tanks.

6. The system of claim 1, further comprising one or more sensors connected to said one or more plating tanks.

7. The system of claim 1, wherein said control system is configured to consecutively operate at least one of the one or more replenishing sections and the one or more draining sections in discrete steps.

8. The system of claim 1, wherein said control system is configured to simultaneously operate at least one of the one or more replenishing sections and the one or more draining sections.

9. A method for depositing metal on semiconductor devices, comprising:
replenishing one or more plating tanks of a plating tool by means of a plurality of replenishment sections, wherein each plating tank contains one of a respective electrolyte solution; and
controlling the draining of the electrolyte solution from said one or more plating tanks by means of one or more draining sections such that the amount of solution the one or more plating tanks are replenished with is drained from the one or more plating tanks, wherein the controlling is performed in dependence on at least one condition of the electrolyte solution.

10. The method of claim 9, wherein the electrolyte solution is replenished to the one or more plating tanks when said electrolyte solution is depleted.

11. The method of claim 9, wherein draining the amount of solution the one or more plating tanks are replenished with is done by means of one or more pumps.

12. The method of claim 9, wherein the amount of solution the one or more plating tanks are replenished with is drained into one or more canisters.

13. The method of claim 9, wherein the method further comprises monitoring said at least one condition of said electrolyte solution in the one or more plating tanks by means of one or more sensors.

14. The method of claim 13, wherein said at least one condition of the respective electrolyte solutions comprises at least one of a total volume of the electrolyte solution, a filling elevation of the electrolyte solution in a plating tank, a parameter of the electrolyte solution relating to an immersion depth of at least one electrode in the electrolyte solution, a concentration of at least one component dissolved in the electrolyte solution, a temperature of the electrolyte solution, an amount of substance of at least one species contained in the electrolyte solution, a current flowing through at least one electrode, a resistivity of the electrolyte solution, a conductivity of the electrolyte solution, a pH value and the like.

15. The method of claim 9, wherein controlling the draining is preformed such that a filling elevation of said electrolyte solution in the one or more plating tanks is kept constant.

16. The method of claim 9, wherein draining the solution from the one or more plating tanks is performed at least one of simultaneously and consecutively with replenishing the one or more plating tanks with said electrolyte solution.

17. The method of claim 9, wherein the method further comprises conditioning the electrolyte solution drained into said one or more canisters for filling up said one or more plating tanks again.
